(19) United States
(12) Patent Application Publication
(10) Pub. No.: US 2019/0198413 A1
(43) Pub. Date: Jun. 27, 2019

(54) SEMICONDUCTOR PACKAGE AND MANUFACTURING METHOD THEREOF

(71) Applicant: KOREA ELECTRONICS TECHNOLOGY INSTITUTE, Seongnam-si, Gyeonggi-do (KR)

(72) Inventors: Jong Min YOOK, Seongnam-si (KR); Jun Chul KIM, Seongnam-si (KR); Dong Su KIM, Seongnam-si (KR)

(21) Appl. No.: 16/225,238

(22) Filed: Dec. 19, 2018

(30) Foreign Application Priority Data
Dec. 20, 2017 (KR) 10-2017-0176295

(51) Int. Cl. H01L 23/31; H01L 23/522; H01L 23/528; H01L 21/56; H01L 23/00

(52) U.S. Cl. CPC H01L 23/3128; H01L 23/5226; H01L 23/5283; H01L 2224/0231; H01L 24/09; H01L 24/17; H01L 2224/02381; H01L 21/565

(57) ABSTRACT

The present invention provides a semiconductor package and a manufacturing method thereof, the semiconductor package including: at least one semiconductor chip; a molding layer surrounding the semiconductor chip; a redistribution layer provided on a first surface of the molding layer to transmit an electrical signal; and at least one connecting element transmitting an electrical signal from the first surface of the molding layer to a second surface of the molding layer. According to the present invention, since the connecting element, which is an independent element capable of transmitting an electrical signal in a vertical direction of the semiconductor package, is included in the molding layer, it is possible to integrate an electric element such as an antenna into a rear surface space of the semiconductor package.

### CROSS REFERENCE TO RELATED APPLICATION

The present application claims priority to Korean Patent Application No. 10-2017-0176295, filed Dec. 20, 2017, the entire contents of which is incorporated herein for all purposes by this reference.

### BACKGROUND OF THE INVENTION

### Field of the Invention

The present invention relates to a semiconductor package and a manufacturing method thereof.

### Description of the Related Art

Recently, with the development of mobile communication technology, demand for a circuit capable of processing a signal of a millimeter wave band has been increased. In addition, there is an attempt to integrate various RF transmitting and receiving parts, such as an antenna and a filter into a chip or package. However, there is demand for a miniaturized and integrated package structure suitable for a high frequency band because an antenna, a filter, and the like occupies a larger area than other parts and accordingly a package size including the same increases.

### DOCUMENTS OF RELATED ART

(Patent Document 1) Korean Patent No. 10-1043471

### SUMMARY OF THE INVENTION

An objective of an embodiment of the present invention is to provide a semiconductor package and a manufacturing method thereof, the semiconductor package including a connecting element which is an independent element capable of transmitting an electrical signal in a vertical direction of the semiconductor package.

In addition, another objective of an embodiment of the present invention is to provide a connecting element configured such that a signal line is formed in the center of the connecting element and a body surrounding the signal line and a shield layer surrounding a side surface of the body are formed whereby the signal line and the shield layer have a structure similar as a coaxial cable.

In addition, still another objective of an embodiment of the present invention is to provide a manufacturing method of a semiconductor package, the manufacturing method including forming of a conductive layer covering a connecting element and a semiconductor chip, wherein the conductive layer covers a side surface of a body of the connecting element such that a coaxial structure is provided.

Furthermore, still another objective of an embodiment of the present invention is to provide a space for an electric element such as an antenna or a filter constituted as a transmission line formed on a rear surface of a semiconductor package by forming at least a part of an upper surface of a conductive layer covering a connecting element and the semiconductor chip 10 flat.

In order to achieve the above objective of the present invention, there is provided a semiconductor package including: at least one semiconductor chip; a molding layer surrounding the semiconductor chip; a redistribution layer provided on a first surface of the molding layer to transmit an electrical signal; and at least one connecting element transmitting an electrical signal from the first surface of the molding layer to a second surface of the molding layer.

The connecting element may include: at least one signal line provided extending from the first surface to the second surface of the molding layer; and a body surrounding and isolating the signal line.

The connecting element may further include: a shield layer formed of a conductive material and configured to surround the body.

The semiconductor package may further include: an electric element provided on the second surface of the molding layer and electrically connected to the connecting element.

The semiconductor package may further include: a base sheet formed of a metal and having multiple accommodating portions accommodating the semiconductor chip and the connecting element.

The semiconductor package may further include: an electrically conductive layer configured to cover at least a part of the semiconductor chip and the connecting element.

The conductive layer may be configured such that at least a part of an upper surface thereof is flat to keep a uniform distance between the second surface of the molding layer and the upper surface of the conductive layer.

The redistribution layer may include at least one first electrode pattern connecting between the semiconductor chip and the connecting element.

The redistribution layer may include: at least one third electrode pattern electrically connected to the shield layer.

In order to achieve the above objective of the present invention, there is provided a manufacturing method of a semiconductor package, the manufacturing method including: disposing at least one semiconductor chip and at least one connecting element on a carrier sheet; forming a molding layer covering and protecting the semiconductor chip and the connecting element; forming a redistribution layer transmitting an electrical signal to a first surface of the molding layer after removing the carrier sheet; and forming an electric element, which is electrically connected to the connecting element, on a second surface of the molding layer. The connecting element includes: at least one signal line provided extending from the first surface to the second surface of the molding layer; and a body surrounding and isolating the signal line.

The disposing of the semiconductor chip and the connecting element may include: disposing a base sheet on the carrier sheet, the base sheet being formed of a metal and having multiple accommodating portions accommodating the semiconductor chip and the connecting element; and disposing the semiconductor chip and the connecting element in the accommodating portions.

the manufacturing method may further include: after the disposing of the semiconductor chip and the connecting element, forming an electrically conductive layer to cover at least a part of the semiconductor chip and the connecting element; and after the forming of the molding layer, removing a part of the second surface of the molding layer and a part of the conductive layer covering the connecting element to expose a signal line of the connecting element.

The above and other objectives, features, and advantages of the present invention will be more clearly understood from the following detailed description when taken in conjunction with the accompanying drawings.

All terms or words used in the specification and claims have the same meaning as commonly understood by one of ordinary skill in the art to which inventive concepts belong. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

According to the embodiment of the present invention, a connecting element, which is an independent element capable of transmitting an electrical signal in a vertical direction of a semiconductor package, is included in a molding layer such that it is possible to integrate an electric element such as an antenna into a rear surface space of the semiconductor package.

According to the embodiment of the present invention, a signal line is formed in the center of a connecting element, and a body surrounding the signal line and a shield layer surrounding a side surface of the body are formed such that the signal line and the shield layer have a structure same as a coaxial cable, whereby an electrical signal of the high frequency band can be stably transmitted.

According to the embodiment of the present invention, at forming of a conductive layer covering a connecting element and a semiconductor chip, the conductive layer covers a side surface of a body of the connecting element such that the conductive layer serves as a shield layer and it is possible to manufacture a structure similar to a coaxial cable without forming a shield layer on the connecting element.

According to the embodiment of the present invention, an upper surface of a conductive layer covering a connecting element and a semiconductor chip is formed flat whereby it is possible to facilitate designing of an antenna or a filter constituted as a transmission line formed on a rear surface of the semiconductor package.

### BRIEF DESCRIPTION OF THE DRAWINGS

The above and other objects, features and other advantages of the present invention will be more clearly understood from the following detailed description when taken in conjunction with the accompanying drawings, in which:

FIG. 1 is a cross-sectional view illustrating a semiconductor package according to an embodiment of the present invention;

FIG. 2 is a cross-sectional view illustrating a semiconductor package in which a shield layer is added to a connecting element according to an embodiment of the present invention;

FIGS. 3A, 3B, 3C, and 3D are a perspective view illustrating connecting elements according to embodiments of the present invention;

FIG. 4 is a cross-sectional view illustrating a semiconductor package to which a conductive layer is added according to an embodiment of the present invention;

FIG. 5 is a cross-sectional view illustrating a semiconductor package in which a conductive layer has a uniform upper surface according to an embodiment of the present invention;

FIG. 6 is a diagram illustrating a process of manufacturing a connecting element according to an embodiment of the present invention;

FIGS. 7 to 11 are diagrams illustrating steps of a manufacturing method of a semiconductor package according to an embodiment of the present invention;

FIGS. 12A, 12B, and 13 to 17 are diagrams illustrating steps of a manufacturing method of a semiconductor package to which a conductive layer is added according to an embodiment of the present invention; and

FIGS. 18 to 21 are diagrams illustrating steps of a manufacturing method of a semiconductor package in which a conductive layer has a uniform upper surface according to an embodiment of the present invention.

### DETAILED DESCRIPTION OF THE INVENTION

The above and other objectives, features, and other advantages of the present invention will be more clearly understood from the following detailed description when taken in conjunction with the accompanying drawings. As for reference numerals associated with parts in the drawings, the same reference numerals will refer to the same or like parts through the drawings. It will be understood that, although the terms “one side”, “the other side”, “first”, “second,” etc. may be used herein to describe various elements, these elements should not be limited by these terms. These terms are only used to distinguish one element from another element. Hereinbelow, in the description, details of well-known features and techniques may be omitted to avoid unnecessarily obscuring the presented embodiments.

Hereinbelow, an embodiment of the present invention will be described in detail with reference to the accompanying drawings.

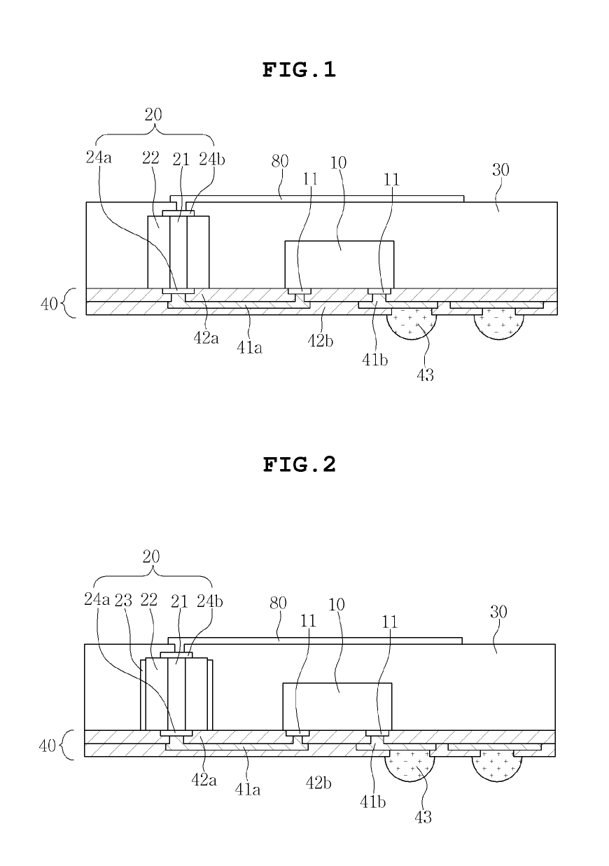

FIG. 1 is a cross-sectional view illustrating a semiconductor package according to an embodiment of the present invention.

As illustrated in FIG. 1, a semiconductor package according to an embodiment of the present invention includes: at least one semiconductor chip 10; a molding layer 30 surrounding the semiconductor chip 10; a redistribution layer 40 provided on a first surface of the molding layer 30 to transmit an electrical signal; and at least one connecting element 20 transmitting an electrical signal from the first surface of the molding layer 30 to a second surface of the molding layer 30. In addition, the semiconductor package according to the embodiment of the present invention further includes an electric element 80 provided on the second surface of the molding layer 30 and electrically connected to the connecting element 20.

The semiconductor chip 10 is an integrated circuit (IC) capable of processing a signal in high frequency band of 3 GHz or more, preferably 30 GHz or more. The semiconductor chip 10 is provided with an input/output terminal 11 on a first surface thereof, but has no input/output terminal 11 on a second surface thereof or is provided with a grounding terminal on the second surface thereof. The first surface of the semiconductor chip 10 on which the input/output terminal 11 is provided is referred to as active face. The semiconductor chip 10 is disposed in a face-down or face-up manner depending on a direction in which the active face faces.

The molding layer 30 covers and protects upper and side surfaces of the semiconductor chip 10, and serves as a base for supporting the semiconductor package. The molding layer 30 is formed of a known material such as an electrical molding compound (EMC) with a molding process or an organic lamination process. The redistribution layer 40 is provided on the first surface of the molding layer 30, which faces the active face of the semiconductor chip 10. On the other hand, the electric element 80 is provided on the second surface of the molding layer 30. The electric element 80 is an antenna, a filter, or the like, or a passive element such as a resistor.

The redistribution layer 40 provided on the first surface of the molding layer 30 includes electrode patterns 41, an insulating layer 42, and a solder 43. The electrode patterns 41 are electrically connected to the input/output terminal 11 of the semiconductor chip 10 and an external circuit or the connecting element 20 to transmit an electrical signal of the semiconductor chip 10. The insulating layer 42 is formed of an electrically insulating material to cover and protect the electrode patterns 41. Specifically, the redistribution layer 40 includes at least one first electrode pattern 41a connecting the semiconductor chip 10 and the connecting element 20. In addition, the redistribution layer 40 includes at least one second electrode pattern 41b connecting the semiconductor chip 10 and an external circuit. The redistribution layer 40 further includes the solder 43 connected to the electrode patterns 41 and providing an electrical and physical connection with an external circuit.

The connecting element 20 includes: at least one signal line 21 extending from the first surface to the second surface of the molding layer 30; and a body 22 surrounding and insulating the signal line 21. The signal line 21 is formed of an electrically conductive material. For example, the signal line 21 is formed of a metal such as copper (Cu), aluminum (Al), silver (Ag), and gold (Au), an alloy containing the same, or an electrically conductive carbon nanotube, nanowire, or the like. The body 22 is formed of an electrically insulating material and is configured to surround the signal line 21 to insulate the signal line 21 from the outside. For example, the body 22 is formed of a material such as ceramic and silicon (Si).

The connecting element 20 further includes: a first cap terminal 24a provided on a first end of the signal line 21; and a second cap terminal 24b provided on a second end of the signal line 21. The first cap terminal 24a and the second cap terminal 24b define a space where the signal line and other elements of the semiconductor package (for example, the electrode patterns 41 and the electric element 80) are connected to each other. Specifically, the first cap terminal 24a is connected to the first electrode pattern 41a, and the second cap terminal 24b is connected to the electric element 80 that is provided on the second surface of the molding layer 30. It is required to ensure a space by partly removing the molding layer 30 such that the electric element 80 is connected to the second cap terminal 24b. A method such as laser processing is used to partly remove the molding layer 30 covering the connecting element 20 and expose the second cap terminal 24b. When performing the laser processing, the second cap terminal 24b prevents the signal line 21 and the body 22 of the connecting element 20 from being damaged.

The connecting element 20 is covered and protected by the molding layer 30 with the semiconductor chip 10. In order to transmit an electrical signal from the first surface to the second surface of the molding layer 30, the connecting element 20 is disposed such that the signal line 21 is vertically disposed. Multiple connecting elements 20 may be included in the semiconductor package. For example, when an antenna is required to be provided on the second surface of the molding layer 30, a requisite number of connecting elements 20 for transmitting a signal of the input/output terminal 11 of the semiconductor chip 10 to the antenna is included inside the molding layer 30.

Conventionally, a structure such as a through molding via (TMV) formed on a molding of a semiconductor package and a through silicon via (TSV) formed on a silicon substrate has been used to transmit an electrical signal from one surface to another surface of a semiconductor package. However, TMV and TSV structures are complicated and costly to manufacture, and there is a problem in that it is impossible to use the entire package when defects occur in forming conductive vias. In addition, in the case of TMV, an area of the conductive via is required to be widened in proportion to the thickness of the molding.

In contrast, the connecting element 20 according to the embodiment of the present invention is an independent element manufactured through a separate manufacturing process, as is the semiconductor chip 10. It is possible to eliminate the occurrence of defects that occur in the conventional TMV and TSV because only connecting elements 20 that are manufactured in a process other than the semiconductor packaging process, go through a separate test, and are determined as a functional product are used for the semiconductor packaging process. In addition, the cost of the embodiment is lower than that of forming TMV or TSV at required positions because an individual unit price of the connecting element 20 is lowered by separate mass-production. Particularly, when the number of electric elements 80 provided on the second surface of the molding layer 30 is few (e.g. one or two), it is relatively expensive to perform the process of forming TMV or TSV for two or three electrical signal transmission paths. In this case, it is economical to form electrical signal transmission paths using the connecting element 20 according to the embodiment of the present invention.

FIG. 2 is a cross-sectional view illustrating a semiconductor package in which a shield layer 23 is added to the connecting element 20 according to an embodiment of the present invention.

As illustrated in FIG. 2, the connecting element 20 according to the embodiment of the present invention further includes the shield layer 23 formed of a conductive material and configured to surround the body 22. The shield layer 23 is formed of an electrically conductive metal such as copper (Cu) and aluminum (Al), or an alloy thereof. The shield layer 23 is configured to surround a side surface of the body 22 in a direction parallel to the signal line 21 such that, when viewed from the outside, a transmission line is provided through which an electrical signal is stably transmitted and the shield layer 23 and the signal line 21 are structured as a coaxial cable when viewed from the outside.

The redistribution layer 40 further includes a third electrode pattern 41c electrically connected to the shield layer 23 of the connecting element 20 in order to stably transmit an electrical signal flowing through the connecting element 20. The shield layer 23 connected to the ground through the third electrode pattern 41c functions as a ground (GND) and as a shield for shielding electromagnetic interference with other transmission lines.

A transmission line transmitting an electrical signal of a high frequency band (a frequency of 3 GHz or more, or 30 GHz or more) is high in energy radiation due to the nature of high frequencies and interacts with other transmission lines, making it difficult for the signal to be transmitted stably. However, the connecting element 20 having the shield layer 23 according to the embodiment of the present invention has a structure in which the signal line 21 and the shield layer 23 have a coaxial structure, and the shield layer 23 is used as the ground (GND). Therefore, there is an advantage in that it is possible to stably transmit an electrical signal of a high frequency band.

It is possible to design and use the connecting element 20 suitable for a frequency band to be used by adjusting factors, such as the thickness and length of the signal line 21, a dielectric constant of the insulating material constituting the body 22, and a distance between the signal line 21 and the shield layer 23, with accordance of the frequency band.

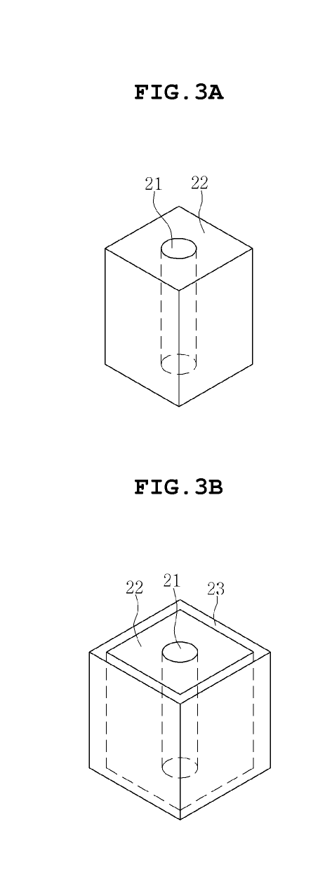

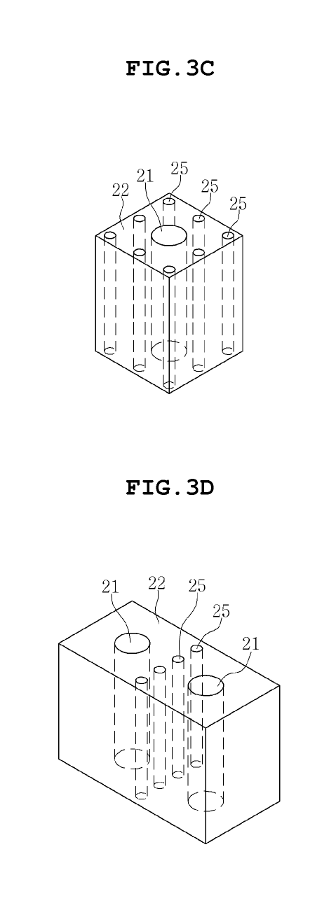

FIGS. 3A, 3B, 3C, and 3D are a perspective view illustrating connecting elements 20 according to embodiments of the present invention.

According to an embodiment of the present invention, a connecting element 20 illustrated in FIG. 3A is structured such that a body 22 has a quadrangular prism shape and a signal line 21 is formed in the center of the body 22 in a manner extending from an upper surface to a lower surface of the body 22 longitudinally. Although not illustrated in the drawing, additional cap terminal 24 may be further provided on the first and second ends of the signal line 21.

A connecting element 20 illustrated in FIG. 3B has a structure in which a shield layer 23 is added to the connecting element 20 illustrated in FIG. 3A. The shield layer 23 is configured to surround the side surface of the body 22. The signal line 21 and the shield layer 23 have a coaxial structure and stably transmits an electrical signal transmitted through the signal line 21.

A connecting element 20 illustrated in FIG. 3C is structured such that a body 22 has a quadrangular prism shape and a signal line 21 is formed in the center of the body 22 in a manner extending from the upper surface to the lower surface of the body 22 longitudinally. In addition, the connecting element 20 includes multiple shield lines 25 provided spaced a predetermined distance apart from the signal line 21, extending from the upper surface to the lower surface of the body 22 in parallel with the signal line 21, and arranged to surround the signal line 21. The shield lines 25 are provided in intervals of about ¼ or less of the wavelength of the electrical signal passing through the signal line 21 such that it is possible to provide a shielding function and a coaxial line. The shield lines 25 may be connected to the third electrode pattern 41c and connected to the ground via the third electrode pattern 41c.

A connecting element 20 illustrated in FIG. 3D is structured such that a body 22 has a quadrangular prism shape and two or more signal lines 21 is formed in the body 22. In addition, the connecting element 20 includes multiple shield lines 25 provided between the signal lines 21 and preventing interference among the signal lines 21. The shield lines 25 are arranged to surround the signal line 21 as illustrated in FIG. 3C or a shield layer 23 may be provided instead of the shield lines 25.

The connecting element 20 is not limited to the embodiments of the present invention illustrated in FIGS. 3A to 3D and includes structures in which the shield layer 23 or the shield lines 25 have a coaxial structure with respect to the signal line 21.

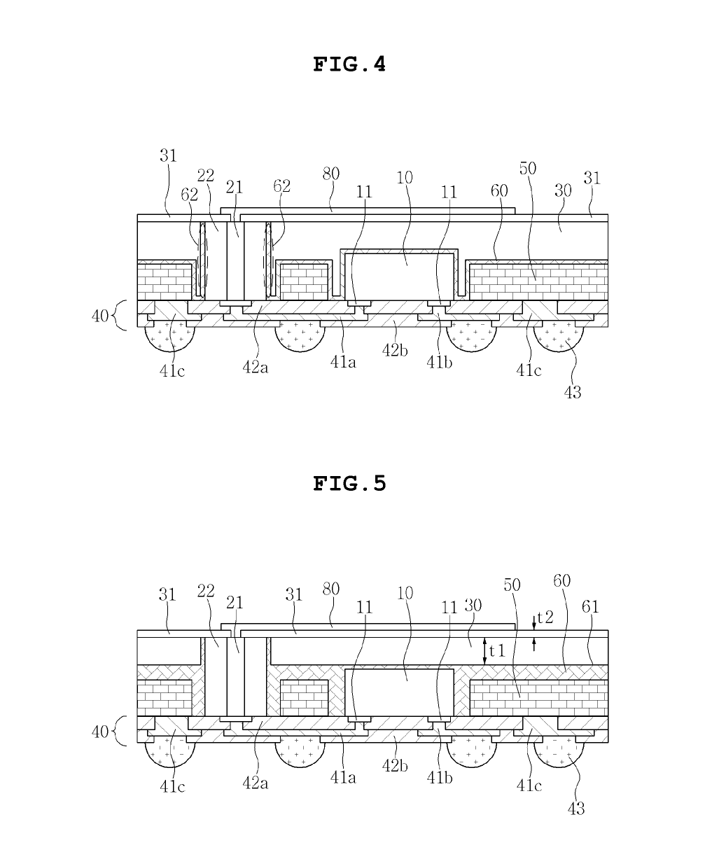

FIG. 4 is a cross-sectional view illustrating a semiconductor package to which a conductive layer 60 is added according to an embodiment of the present invention.

As illustrated in FIG. 4, the semiconductor package according to the embodiment of the present invention further includes the electrically conductive layer 60 configured to cover at least a part of the semiconductor chip 10 and the connecting element 20. Specifically, the semiconductor package according to the embodiment of the present invention further includes the electrically conductive layer 60 that covers at least a part of a base sheet 50, the semiconductor chip 10, and the connecting element 20, the base sheet 50 formed of a metal and having multiple accommodating portions 51 accommodating at least one semiconductor chip 10 and at least one connecting element.

The conductive layer 60 is formed of an electrically conductive metal such as copper (Cu) and aluminum (Al), or an alloy thereof. The conductive layer 60 is configured to cover rear and side surfaces of the semiconductor chip 10 to receive heat generated from the semiconductor chip 10 and discharge the heat to the outside. The conductive layer 60 is configured to cover an area 62 of the side surface of the body 22 of the connecting element 20 such that the conductive layer 60 functions in the same manner as the shield layer 23 described above. Since the conductive layer 60 is configured to cover the semiconductor chip 10 and the connecting element 20, the conductive layer 60 serves as a shield layer for shielding the semiconductor chip 10 and the connecting element 20 from an effect of external electromagnetic change.

The base sheet 50 has the multiple accommodating portions 51 accommodating the semiconductor chip 10 and the connecting element 20. The semiconductor chip 10 and the connecting element 20 are accommodated in the accommodating portions 51 formed in the base sheet 50, and the conductive layer 60 covers the base sheet 50, the semiconductor chip 10, and the connecting element 20. The base sheet 50 is formed of an electrically conductive metal such as copper (Cu) and aluminum (Al), or an alloy thereof. Heat generated in the semiconductor chip 10 is transferred to the conductive layer 60 to the base sheet 50 such that the heat is released to the outside through the third electrode pattern 41c connected to the base sheet 50.

Since the conductive layer 60 and the base sheet 50 are formed of electrically conductive materials, the conductive layer 60 and the base sheet 50 are connected to the external ground through the third electrode pattern 41c electrically connected to the base sheet 50 or the conductive layer 60 and thus function as grounds (GND). A rear insulating layer 31 is provided on the second surface of the molding layer 30 for electrical insulation between the conductive layer 60 provided on the side surface of the connecting element 20 and the electric element 80 provided on the second surface of the molding layer 30. The electric element 80 is formed on the rear insulating layer 31. If necessary, the electric element 80 may be electrically connected to the conductive layer 60, which functions as a ground.

FIG. 5 is a cross-sectional view illustrating a semiconductor package in which a conductive layer 60 has a uniform upper surface 61 according to an embodiment of the present invention.

As illustrated in FIG. 5, the conductive layer 60 according to the embodiment of the present invention is configured such that at least a part of the upper surface 61 thereof is flat to keep a uniform distance between the second surface of the molding layer 30 and the upper surface 61 of the conductive layer 60. A value obtained by adding a distance t1 between the upper surface 61 of the conductive layer 60 and the second surface of the molding layer 30 and a thickness t2 of the rear insulating layer 31 is a distance (t1 t2) between the electric element 80 and the ground. An area where the upper surface 61 of the conductive layer 60 is flat corresponds to an area where the electric element 80 is formed on the second surface of the molding layer 30. The top surface of the semiconductor chip 10 is located higher than that of the base sheet 50 as illustrated in FIG. 5. Thus, it is possible to form the upper surface 61 of the conductive layer 60 flat by forming the conductive layer 60 on the base sheet 50 on the basis of a part of the upper surface of the conductive layer 60 which is formed on the semiconductor chip 10.

In designing an antenna and a filter using an electrical signal of a high frequency band (a frequency of 3 GHz or more, or 30 GHz or more), it is required to consider factors such as a linewidth and a length of the transmission line constituting the antenna or the filter, a distance between the transmission line and the ground (GND), and a dielectric constant of the insulating material between the ground and the transmission line due to the nature of the high frequency band. In particular, assuming that it is possible to reduce the distance between the transmission line and the ground, the linewidth of the transmission line can be reduced and a design for minimizing influences of parasitic elements can be achieved.

The height of the connecting element 20 is greater than that of the semiconductor chip 10. Since the conductive layer 60 is configured to cover an inactive surface of the semiconductor chip 10, the upper surface 61 of the conductive layer 60 is positioned to be higher than the top surface of the semiconductor chip 10. Therefore, in order to provide the molding layer 30 on the conductive layer 60 and form the rear insulating layer 31 and the electric element 80 on the top, forming the height of the connecting element 20 to be higher than the that of the semiconductor chip 10 is advantageous in terms of simplifying the process.

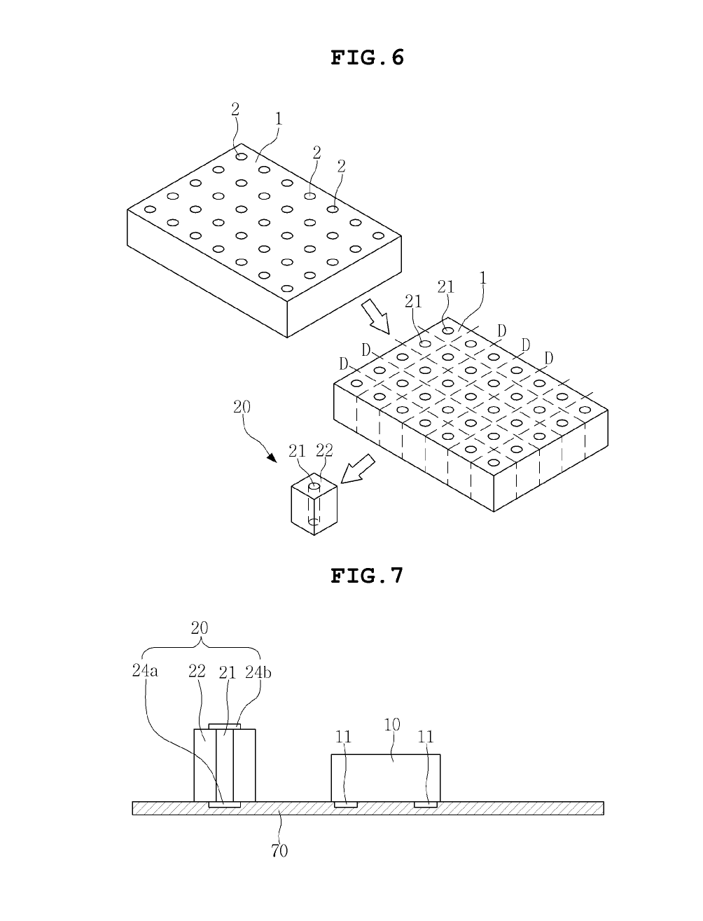

FIG. 6 is a diagram illustrating a process of manufacturing a connecting element 20 according to an embodiment of the present invention.

As illustrated in FIG. 6, a substrate formed of an electrically insulating material such as ceramic or silicon (Si) is prepared. Via holes are formed in the substrate so as to extend from the top surface to the bottom surface of the substrate. A size of the via holes is determined according to a frequency of an electrical signal to be transmitted. Each of the via holes formed in the substrate is filled with an electrically conductive material such as copper (Cu) or aluminum (Al) to form a signal line 21. Filling of the electrically conductive material is accomplished using known methods such as electroplating, sputtering, and chemical vapor deposition (CVD). After the multiple signal lines 21 are formed on the substrate, the substrate is cut along a cut line D to form a connecting element 20.

At forming of the via holes in the substrate, it is possible that a via hole to be a signal line 21 is formed in the center and multiple via holes to be shield lines 25 are formed around the via hole to be the signal line 21 such that the signal line 21 and the shield lines 25 are formed simultaneously. In addition, after forming the signal line 21, it is possible that cap terminals are further provided on first and second ends of the signal line 21 and then the substrate is cut.

FIGS. 7 to 11 are diagrams illustrating steps of a manufacturing method of a semiconductor package according to an embodiment of the present invention.

A manufacturing method of a semiconductor package according to an embodiment of the present invention includes: disposing at least one semiconductor chip 10 and at least one connecting element 20 on a carrier sheet 70; forming a molding layer 30 covering and protecting the semiconductor chip 10 and the connecting element 20; forming a redistribution layer 40 transmitting an electrical signal to a first surface of the molding layer 30 after removing the carrier sheet 70; and forming an electric element 80, which is electrically connected to the connecting element 20, on a second surface of the molding layer 30. Here, the connecting element 20 includes: at least one signal line 21 extending from the first surface to the second surface of the molding layer 30; and a body 22 surrounding and insulating the signal line 21.

As illustrated in FIG. 7, the semiconductor chip 10 and the connecting element 20 are disposed on the carrier sheet 70. The semiconductor chip 10 is disposed in a face-down manner such that an active surface thereof faces downward, and the connection device 20 is disposed such that the signal line 21 is erect.

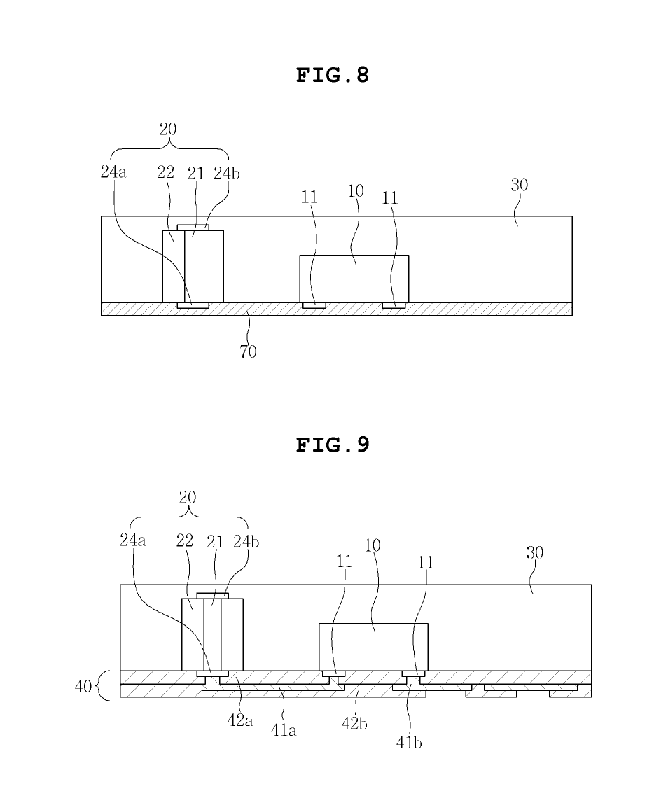

As illustrated in FIG. 8, the molding layer 30 is formed to cover and protect the semiconductor chip 10 and the connecting element 20. The molding layer 30 is formed of a known material such as an epoxy molding compound (EMC) with a process such as a molding process and an organic lamination process. Here, a surface of the molding layer 30 at the active surface side of the semiconductor chip 10 is referred to as the first surface of the molding layer 30, and the opposite surface is referred to as the second surface. The second surface of the molding layer 30 is formed to have a height capable of covering a second cap terminal 24b of the connecting element 20.

As illustrated in FIG. 9, the carrier sheet 70 is removed and the redistribution layer 40 is formed. A first insulating layer 42a is formed in a place where the carrier sheet 70 is removed. Then, a part of the first insulating layer 42a in a region corresponding to a first cap terminal 24a of the connecting element 20 and an input/output terminal 11 of the semiconductor chip 10 is removed. A first electrode pattern 41a, which connects the input/output terminal 11 of the semiconductor chip 10 and the first cap terminal 24a, and a second electrode pattern 41b, which electrically connects the input/output terminal 11 of the semiconductor chip 10 to an external substrate, are formed. A second insulating layer 42b is formed on the first insulating layer 42a to cover and protect the first electrode pattern 41a and the second electrode pattern 41b. A part of the second insulating layer 42b is removed to expose a part of the second electrode pattern 41b.

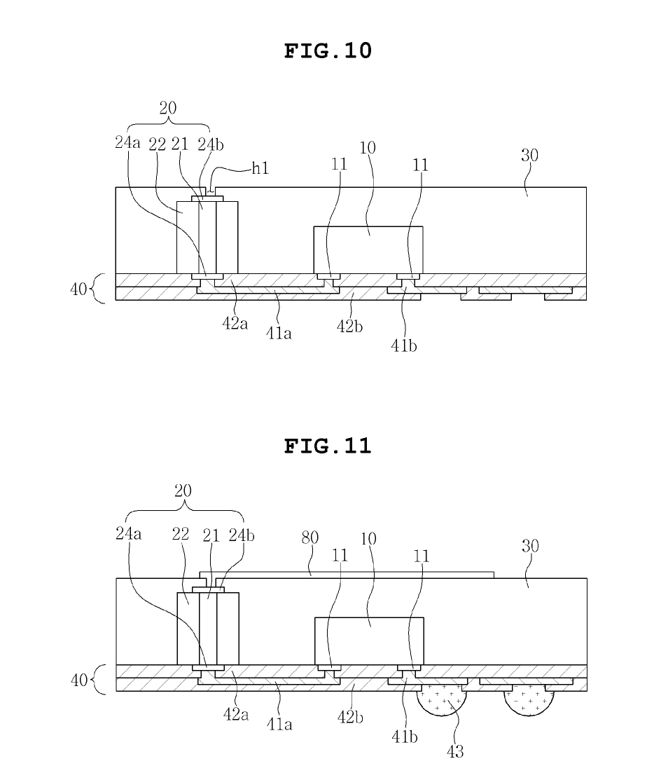

As illustrated in FIG. 10, an area h1 of the molding layer 30, which corresponds to the second terminal cap connected to the signal line 21, is removed such that the connecting element 20 transmits an electrical signal to the second surface of the molding layer 30. The removal of the molding layer 30 is performed using a laser processing method or other known methods.

As illustrated in FIG. 11, the electric element 80 connected to the exposed second terminal cap and formed on the second surface of the molding layer 30 is formed. The electric element 80 is an antenna, a filter, or the like manufactured by forming a transmission line using pattern plating method or other methods. The solder 43 is formed on the exposed region of the second electrode pattern 41b.

Through the process, it is possible to manufacture the semiconductor package illustrated in FIG. 1. It is possible to manufacture the semiconductor package illustrated in FIG. 2 when using a connecting element 20 having a shield layer 23 in the process and forming a third electrode pattern 41c connected to the shield layer 23 in the process of forming the electrode pattern.

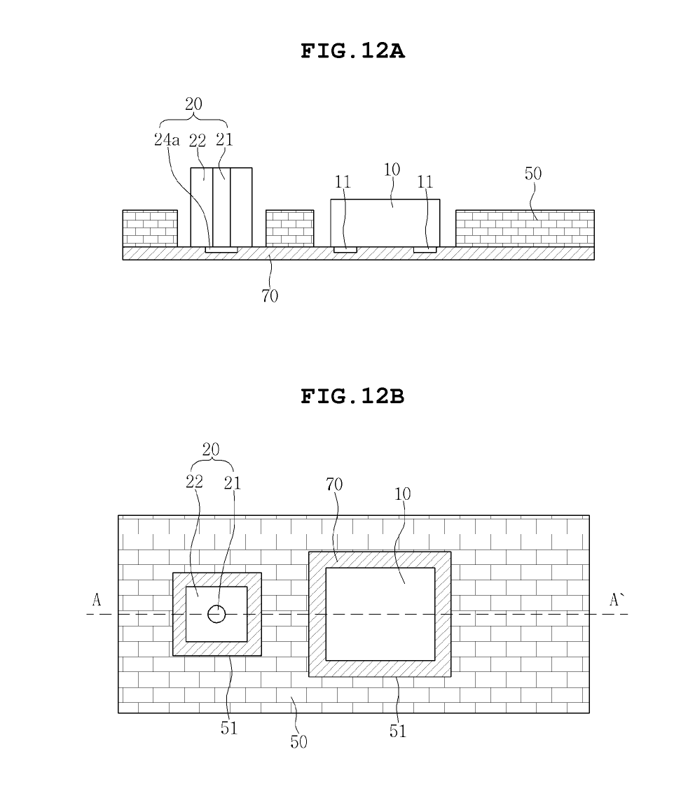

FIGS. 12A, 12B, and 13 to 17 are diagrams illustrating steps of a manufacturing method of a semiconductor package to which a conductive layer 60 is added according to an embodiment of the present invention.

A manufacturing method of a semiconductor package according to an embodiment of the present invention includes: disposing a base sheet 50 on a carrier sheet 70, the base sheet 50 being formed of a metal and having multiple accommodating portions 51 accommodating a semiconductor chip 10 and a connecting element 20; disposing the semiconductor chip 10 and the connecting element 20 in the accommodating portions 51; after the disposing steps, forming an electrically conductive layer 60 to cover at least a part of the semiconductor chip 10 and the connecting element 20; forming a molding layer 30 covering and protecting the semiconductor chip 10 and the connecting element 20; forming a redistribution layer 40 transmitting an electrical signal to a first surface of the molding layer 30 after removing the carrier sheet 70; after the forming of the molding layer 30, removing a part of the second surface of the molding layer 30 and a part of the conductive layer 60 covering the connecting element 20 to expose a signal line 21 of the connecting element 20; and forming an electric element 80, which is electrically connected to the connecting element 20, on a second surface of the molding layer 30.

FIG. 12B is a top view of FIG. 12A, and FIG. 12A is a cross-sectional view taken along line A-A′ of FIG. 12B.

As illustrated in FIG. 12A, the base sheet 50 is disposed on the carrier sheet 70, the base sheet 50 formed of a metal and having the multiple accommodating portions 51 accommodating the semiconductor chip 10 and the connecting element 20. As illustrated in FIG. 12B, the accommodating portions 51 are formed to have a size corresponding to sizes of the connecting element 20 and the semiconductor chip 10. The semiconductor chip 10 and the connecting element 20 are disposed in the accommodating portions 51 formed in the base sheet 50.

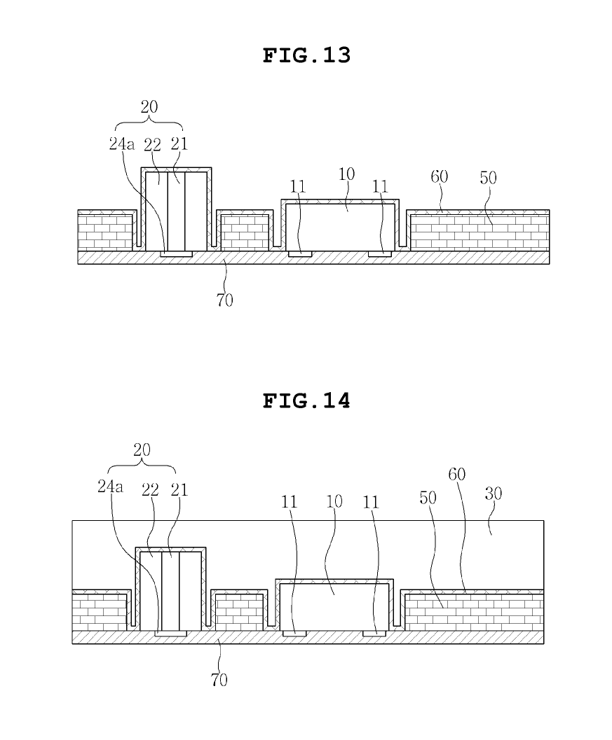

As illustrated in FIG. 13, the conductive layer 60 is formed to cover the base sheet 50, the connecting element 20, and the semiconductor chip 10. The conductive layer 60 may be formed to cover side and upper surfaces of the connecting element 20. The conductive layer 60 is formed in a layer form using copper (Cu), aluminum (Al), or the like using a known method such as electroplating, sputtering, and chemical vapor deposition (CVD).

As illustrated in FIG. 14, the molding layer 30 is formed on the conductive layer 60. The content of the molding layer 30 is the same as described above.

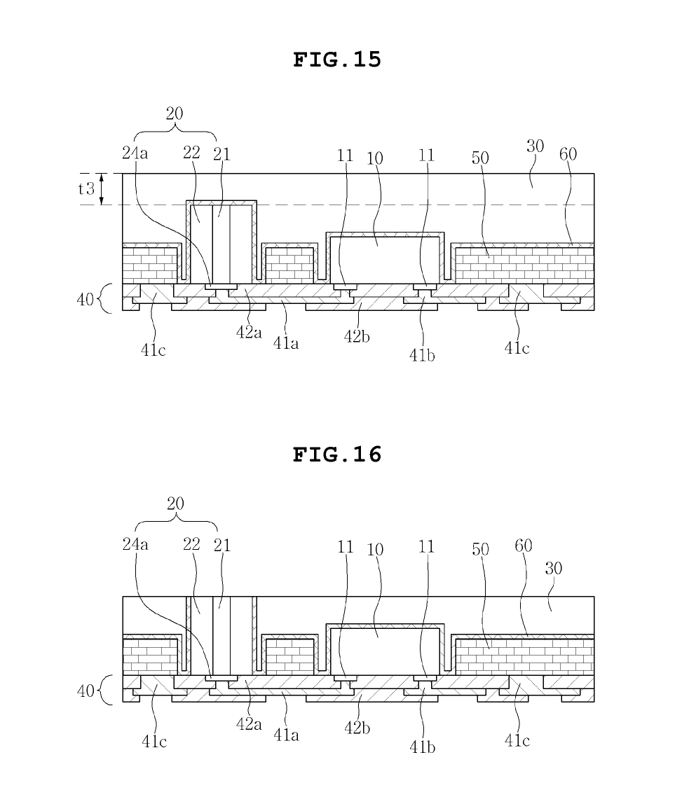

As illustrated in FIG. 15, the redistribution layer 40 is formed after the carrier sheet 70 is removed. When forming the first electrode pattern 41a and the second electrode pattern 41b, a third electrode pattern 41c electrically connected to the base sheet 50 may be formed additionally.

As illustrated in FIG. 16, a part of the second surface of the molding layer 30 and a part of the conductive layer 60 covering the connecting element 20 are removed to expose the signal line 21 of the connecting element 20. Here, the molding layer 30 is removed by a thickness t3 illustrated in FIG. 15.

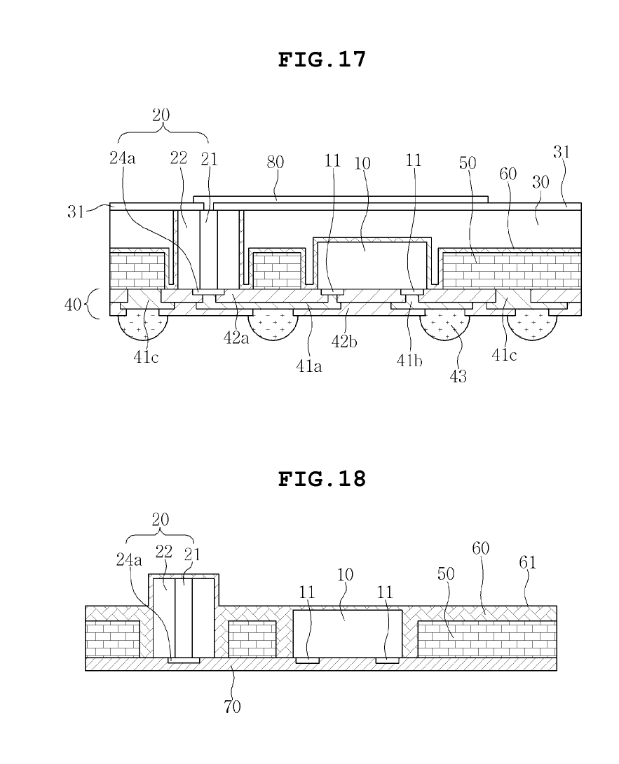

As in FIG. 17, a rear insulating layer 31 is formed on the second surface of the molding layer 30. The corresponding region of the rear insulating layer 31 is partially removed to expose the signal line 21, and thus the electric element 80 connected to the signal line 21 is formed.

As illustrated in FIG. 18, in the state that the base sheet 50 is disposed on the carrier sheet 70 and the connecting element 20 and the semiconductor chip 10 are disposed in the accommodating portions 51, the conductive layer 60 is formed such that at least a part of the upper surface 61 of the conductive layer 60 is to be flat to keep a uniform distance between the second surface of the conductive layer 60 and the upper surface 61 of the conductive layer 60.

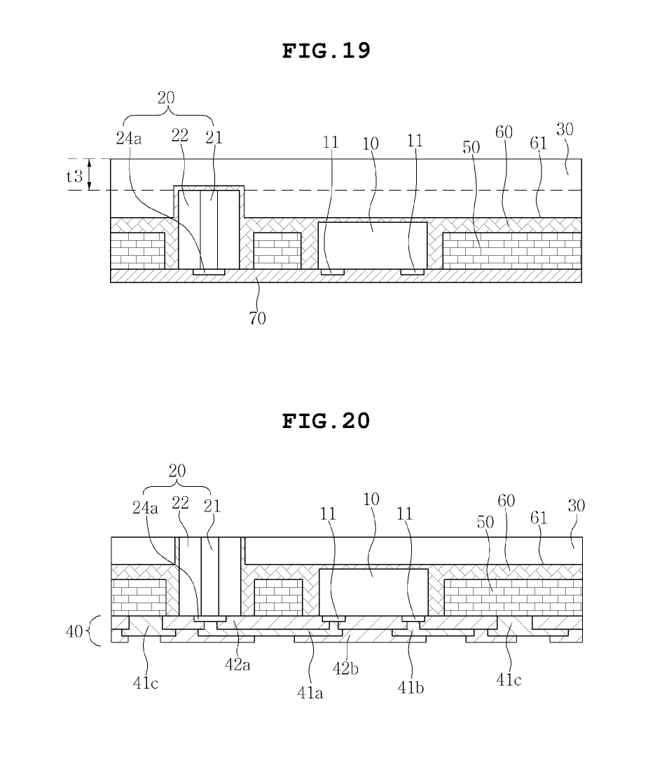

As illustrated in FIG. 19, the molding layer 30 is formed on the conductive layer 60. As illustrated in FIG. 20, the carrier sheet 70 is removed and the redistribution layer 40 is formed. A part of the second surface of the molding layer 30 and a part of the conductive layer 60 are removed to expose the signal line 21.

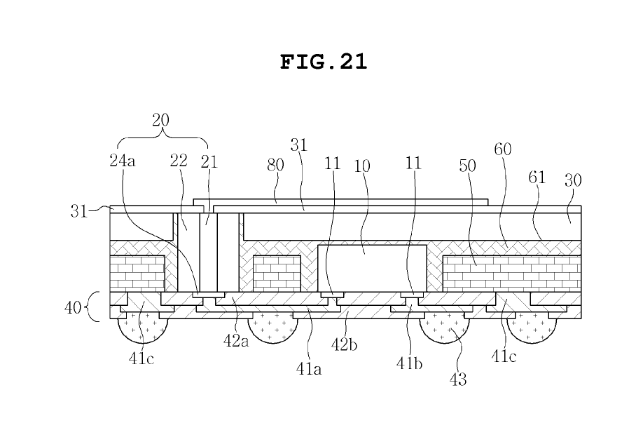

As illustrated in FIG. 21, the rear insulating layer 31 is formed on the second surface of the molding layer 30 and the electric element 80 connected to the signal line 21 is formed on the rear insulating layer 31.

According to the embodiment of the present invention, the connecting element 20, which is an independent element capable of transmitting an electrical signal in a vertical direction of the semiconductor package, is included in the molding layer 30 such that it is possible to integrate the electric element 80 such as an antenna into a rear surface space of the semiconductor package.

According to the embodiment of the present invention, a signal line 21 is formed in the center of the connecting element 20 and the body 22 surrounding the signal line 21 and the shield layer 23 surrounding the side surface of the body 22 are formed such that the signal line 21 and the shield layer 23 have a structure same as a coaxial cable, whereby an electrical signal of the high frequency band can be stably transmitted.

According to the embodiment of the present invention, at forming of the conductive layer 60 covering the connecting element 20 and the semiconductor chip 10, the conductive layer 60 covers the side surface of the body 22 of the connecting element 20 such that the conductive layer 60 serves as the shield layer 23 and it is possible to manufacture a structure similar to a coaxial cable without forming the shield layer 23 on the connecting element 20.

According to the embodiment of the present invention, the upper surface 61 of the conductive layer 60 covering the connecting element 20 and the semiconductor chip 10 is formed flat whereby it is possible to facilitate designing of an antenna or a filter constituted as the transmission line formed on the rear surface of the semiconductor package.

Although the preferred embodiments of the present invention have been disclosed for illustrative purposes, those skilled in the art will appreciate that various modifications, additions and substitutions are possible, without departing from the scope and spirit of the invention as disclosed in the accompanying claims. It is thus well known to those skilled in that art that the present invention is not limited to the embodiment disclosed in the detailed description.

The scope of the present invention is defined by the accompanying claims rather than the description which is presented above. Moreover, the present invention is intended to cover not only the exemplary embodiments, but also various alternatives, modifications, equivalents and other embodiments that may be included within the spirit and scope of the present invention as defined by the appended claims.

What is claimed is:

1. A semiconductor package comprising:
at least one semiconductor chip;
a molding layer surrounding the semiconductor chip;
a redistribution layer provided on a first surface of the molding layer to transmit an electrical signal; and
at least one connecting element transmitting an electrical signal from the first surface of the molding layer to a second surface of the molding layer.

2. The semiconductor package of claim 1, wherein the connecting element includes:
at least one signal line provided extending from the first surface to the second surface of the molding layer; and
a body surrounding and isolating the signal line.

3. The semiconductor package of claim 2, wherein the connecting element further includes:
a shield layer formed of a conductive material and configured to surround the body.

4. The semiconductor package of claim 1, further comprising:
an electric element provided on the second surface of the molding layer and electrically connected to the connecting element.

5. The semiconductor package of claim 1, further comprising:
a base sheet formed of a metal and having multiple accommodating portions accommodating the semiconductor chip and the connecting element.

6. The semiconductor package of claim 1, further comprising:
an electrically conductive layer configured to cover at least a part of the semiconductor chip and the connecting element.

7. The semiconductor package of claim 6, wherein the conductive layer is configured such that at least a part of an upper surface thereof is flat to keep a uniform distance between the second surface of the molding layer and the upper surface of the conductive layer.

8. The semiconductor package of claim 1, wherein the redistribution layer includes at least one first electrode pattern connecting between the semiconductor chip and the connecting element.

9. The semiconductor package of claim 3, wherein the redistribution layer includes:
at least one third electrode pattern electrically connected to the shield layer.

10. A manufacturing method of a semiconductor package, the manufacturing method comprising:
disposing at least one semiconductor chip and at least one connecting element on a carrier sheet;
forming a molding layer covering and protecting the semiconductor chip and the connecting element;
forming a redistribution layer transmitting an electrical signal to a first surface of the molding layer after removing the carrier sheet; and
forming an electric element, which is electrically connected to the connecting element, on a second surface of the molding layer,
wherein the connecting element includes:
at least one signal line provided extending from the first surface to the second surface of the molding layer; and
a body surrounding and isolating the signal line.

11. The manufacturing method of claim 10, wherein the disposing of the semiconductor chip and the connecting element includes:
disposing a base sheet on the carrier sheet, the base sheet being formed of a metal and having multiple accommodating portions accommodating the semiconductor chip and the connecting element; and
disposing the semiconductor chip and the connecting element in the accommodating portions.

12. The manufacturing method of claim 10, further comprising:
after the disposing of the semiconductor chip and the connecting element, forming an electrically conductive layer to cover at least a part of the semiconductor chip and the connecting element; and
after the forming of the molding layer, removing a part of the second surface of the molding layer and a part of the conductive layer covering the connecting element to expose a signal line of the connecting element.
